(19) United States
(12) Patent Application Publication
(10) Pub. No.: US 2025/0174455 A1
(43) Pub. Date: May 29, 2025

(54) HIGH QUALITY NITRIDE AND OXIDE FABRICATION AND SYSTEM

(71) Applicant: Texas Instruments Incorporated, Dallas, TX (US)

(72) Inventors: Saiful Islam, Lehi, UT (US); Gavin Wardle, South Jordan, UT (US)

(21) Appl. No.: 18/952,888

(22) Filed: Nov. 19, 2024

Related U.S. Application Data
(60) Provisional application No. 63/604,137, filed on Nov. 29, 2023.

(51) Int. Cl. H01L 21/02; C23C 16/34; C23C 16/40; C23C 16/56; H01L 21/3065; H01L 21/311

(52) U.S. Cl. CPC H01L 21/0217; C23C 16/345; C23C 16/402; C23C 16/56; H01L 21/02164; H01L 21/3065; H01L 21/31111

(57) ABSTRACT

A method of forming at least one of a nitride or oxide layer for an integrated circuit, the method comprising: (i) positioning a semiconductor wafer in a processing chamber, the semiconductor wafer including a wafer front side and the processing chamber including differential surfaces adapted to be coupled to a plasma-igniting external radio frequency source; (ii) depositing one of a nitride or oxide on at least an exposed portion of either the semiconductor wafer or a layer affixed relative to the wafer front side by reacting at least two precursor gases for a selected one of the nitride or oxide layer in the chamber while the plasma igniting external radio frequency source is enabled; and (iii) post-treating the one of a nitride or oxide with the plasma igniting external radio frequency source enabled and with exposure to helium and nitrogen in the absence of at least one of the at least two precursor gases.

### CROSS-REFERENCE TO RELATED APPLICATION

This application claims priority to, the benefit of the filing date of, and hereby incorporates herein by reference: U.S. Provisional Patent Application No. 63/604,137, entitled “PECVD Front side High Quality Nitride and Oxide Processes,” filed Nov. 29, 2023.

### BACKGROUND

The described examples relate to semiconductor fabrication, for example with respect to forming silicon nitride layers and silicon oxide layers in integrated circuits (ICs).

ICs pervade all manners of electronic devices, and material layers (or “films”) often used in many of those ICs are silicon nitride and silicon oxide (sometimes referred to simply as “nitride” and “oxide”). For example, in flash memory structures, any one or more of blanket and/or conformal nitrides, conformal nitrides, and blanket and/or conformal oxides may be implemented. Such layers may be used in connection with position, isolation, and function of each of the flash memory floating gate, control gate, and erase gate. Each or all of these layers also may be implemented in other types of IC devices.

In some procedures, nitride and oxide layers have been formed using furnace-based batch processing, that is, of a relatively large number (e.g., 125) of wafers in a furnace at a time. Such films may be referred to as “thermal nitrides” or “thermal oxides”. This approach often involves relatively long heat cycles (e.g., multiple hours) and relatively high temperatures (e.g., 700° C. and above). These processes form the layers on both the front side and back side of a semiconductor wafer, and to the extent such layers are subsequently undesirable on the wafer back side, additional steps, costs, time, and often chemicals are required to remove such layers. Otherwise, these processes may provide satisfactory film attributes, but these heat cycles and temperatures can provide additional drawbacks.

Accordingly, there may be a need to provide improved IC nitride and oxide layers, and this document provides implementations that may improve on certain of the above concepts, as detailed below.

### SUMMARY

A method of forming at least one of a nitride or oxide layer for an integrated circuit, the method comprising: (i) positioning a semiconductor wafer in a processing chamber, the semiconductor wafer including a wafer front side and the processing chamber including differential surfaces adapted to be coupled to a plasma-igniting external radio frequency source; (ii) depositing one of a nitride or oxide on at least an exposed portion of either the semiconductor wafer or a layer affixed relative to the wafer front side by reacting at least two precursor gases for a selected one of the nitride or oxide layer in the chamber while the plasma igniting external radio frequency source is enabled; and (iii) post-treating the one of a nitride or oxide with the plasma igniting external radio frequency source enabled and with exposure to helium and nitrogen in the absence of at least one of the at least two precursor gases.

Other aspects are also described and claimed.

### BRIEF DESCRIPTION OF THE DRAWINGS

FIG. 1 is a block diagram of an IC fabrication system.

FIG. 2 is a flow diagram of an example for operating the FIG. 1 system.

FIG. 3A illustrates a cross-section of a number of blanket dielectric layers over a semiconductor substrate.

FIG. 3B illustrates the FIG. 3A structure after the addition of two additional blanket dielectric layers.

FIG. 3C illustrates the FIG. 3B structure after additional processing steps, including the formation of stacks and two conformal layers.

FIG. 3D illustrates the FIG. 3C structure after additional processing steps, including the formation of sidewall spacers and floating gates.

### DETAILED DESCRIPTION

Various disclosed methods and devices of the present disclosure may be beneficially employed in aspects of semiconductor technology, e.g. by replacing furnace-grown dielectric layers, that would otherwise be formed on a wafer backside, with plasma-deposited dielectric layers of similar quality as the analogous furnace-grown films and are confined to the wafer front side. While such examples may be expected to reduce process complexity or improve thermal budget management of the production wafer, no particular result is a requirement unless explicitly recited in a particular claim.

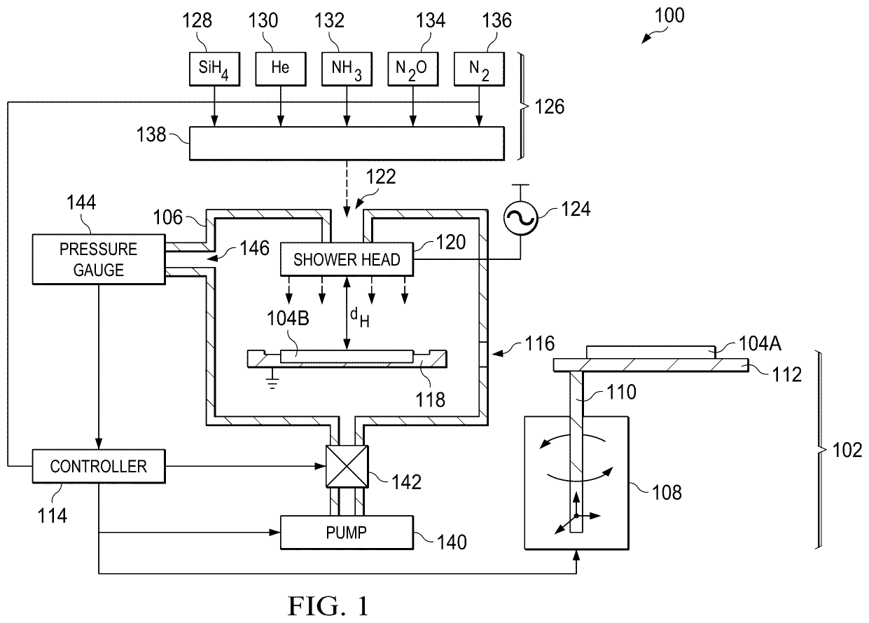

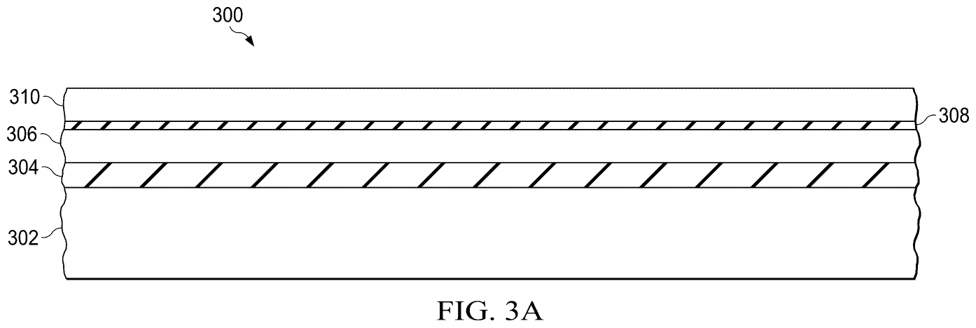

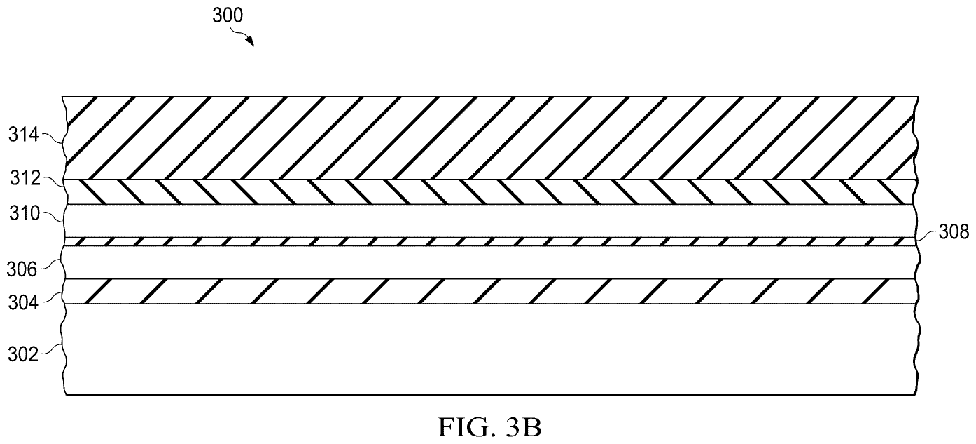

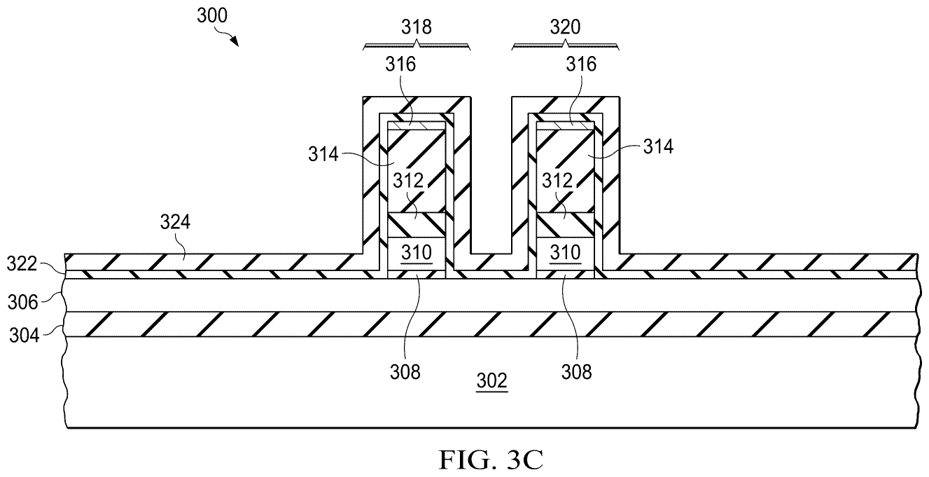

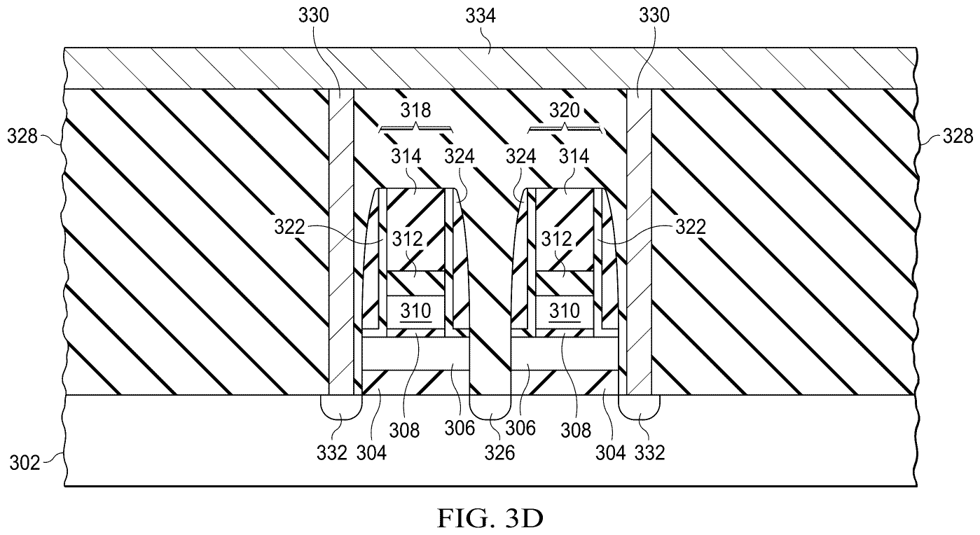

FIG. 1 is a block diagram of an IC fabrication system 100, as may be used as an example for forming a high quality nitride and/or oxide layer (sometimes referred to as a film). The layer may be implemented in various IC structures, with a flash memory as an example as illustrated later in FIGS. 3A-3D. The system 100 has some attributes known in the art, but is improved as further detailed in this document. Accordingly, only certain aspects are illustrated. In an example, the system 100 simultaneously processes a relatively small number, such as one or two, semiconductor wafers. The processing may include plasma enhanced chemical vapor deposition (PECVD) of the desired layer(s).

The system 100 includes a robotic handler 102, for moving a semiconductor (e.g., silicon) wafer 104 between the robotic handler 102 and a process chamber 106—for sake of reference, FIG. 1 illustrates the semiconductor wafer 104 as the semiconductor wafer 104A when supported by the robotic handler 102 and as the semiconductor wafer 104B when inside the process chamber 106 (or collectively, as the semiconductor wafer 104A/104B). The semiconductor wafer 104A may be positioned relative to the robotic handler 102 in cooperation with other apparatus, for example as received from a wafer cassette or a front opening unified (or universal) pod (FOUP). The semiconductor wafer 104A also may travel to various other locations for processing, for example for additional steps before and/or after being processed in the process chamber 106. Further, while FIG. 1 illustrates the process chamber 106 as the sole chamber within reach or proximity of the robotic handler 102, other chambers likewise may be within the same proximity, including others that perform other steps in forming other structures (e.g., nitriding, annealing, polysilicon deposition, and the like).

The robotic handler 102 includes an actuator 108, coupled to and operable to change positions of a shaft 110. The actuator 108 may move the shaft 110 in different directions, including vertically, rotationally, and laterally, as FIG. 1 illustrates via arrows. The shaft 110 is coupled to a platform 112, on which the semiconductor wafer 104A is supported. The system 100 also includes a controller 114, or multiple controllers, which may or may not communicate with other controllers, and the controller 114 directs the actuator 108 movement and, accordingly, movement of the semiconductor wafer 104A. The controller(s) 114 are programmable/computational devices, known in the art, and include various manners of hardware and software for controlling semiconductor wafer processing. For example, such hardware may include a microprocessor (including a digital signal processor) or microcontroller, computer readable media such as memory, or access to memory, for reading/writing data and programming, and communications (including networking) interfaces for input/output, for example including a user interface through which a user can input, or choose, and execute wafer processing parameters, sometimes referred to in part as a recipe. The software, associated with and stored in the computer-readable media of, the controller(s) 114, provides program instructions to the controller hardware, so as to control various processing steps described in this document.

The process chamber 106 includes aspects for receiving and processing the semiconductor wafer 104B. For example, the process chamber 106 includes a first passageway 116, which is proximate the robotic handler 102, and through which the semiconductor wafer 104A/104B is passed to and from the process chamber 106 interior. Specifically, the robotic handler 102 transfers the semiconductor wafer 104A through the first passageway 116 and positions it as the semiconductor wafer 104B within a support platform 118 (e.g., edge ring) that is affixed within the process chamber 106 interior (e.g., to a chuck, not shown). Once the semiconductor wafer 104B is so positioned, the first passageway 116 is closed, and the semiconductor wafer 104B is processed as further described below. The support platform 118 may be heatable directly, or be coupled to, or within the vicinity of a separate heater (not shown), for controlling temperature inside the process chamber 106 and of the surface of the semiconductor wafer 104B. The support platform 118 is also electrically connected to ground. Once the processing is complete, the first passageway 116 is opened, and the robotic handler 102 retrieves the semiconductor wafer 104B from the process chamber 106 interior, after which the semiconductor wafer 104A/104B is passed to an additional chamber, or possibly a sequence of respective chambers, for additional processing steps. The process chamber 106 also includes a shower head 120 for receiving one or more externally-supplied gases through a second passageway 122, and for then distributing the gas(es) into the chamber interior. For later reference, the shower head 120 is positioned at a distance du from the upper surface of the semiconductor wafer 104B. The shower head 120 is also electrically connected to an external radio frequency (RF) source 124. When the external RF source 124 is enabled, it provides an electrical signal that creates a differential potential between the shower head 120 and the grounded support platform 118, as part of the plasma-generation operation of the system 100. Also while not shown, the interior of the process chamber 106 may include other elements, such as a window and reflectors, possibly water cooled, for isolating and directing heat toward the semiconductor wafer 104B.

To the top in FIG. 1, the IC fabrication system 100 also includes a gas distribution system 126. The gas distribution system 126 includes a number of different gas sources, where in the illustrated example there are five such sources: (i) a silane (SiH₄) source 128; (ii) a helium (He) source 130; (iii) an ammonia (NH₃) source 132; (iv) a nitrous oxide (N₂O) source 134; and (v) a nitrogen (N₂) source 136. The flow of each of these gas sources is under control of the controller 114. Each of the gas sources 128 through 136 is coupled to a supply chamber 138 that fluidly communicates with the second passageway 122, which may include the use of one or more additional valves (not show) that also may be controlled by the controller 114. The supply chamber 138 may include various separate apparatus not shown, such as a manifold, mixing chamber, and a mass flow controller(s)). Accordingly, when the second passageway 122 is opened, the selected gas(es) in the supply chamber 138 pass to the interior of the process chamber 106.

Lastly, the system 100 includes a pump 140, a valve 142 in the fluid communication path between the pump 140 and the interior of the process chamber 106, and a pressure gauge 144 also in fluid communication via a respective passageway 146 with the interior of the process chamber 106. Collectively, these apparatus maintain the proper environment and ensure quality and consistency of the deposition process. For example, the pump 140 may create vacuum within the process chamber 106, remove gas from it, maintain pressure, and assist with stabilizing and maintaining pressure before the introduction of precursor gases and plasma ignition. Relatedly, the pressure gauge 144 permits precise and safety-related pressure monitoring and feedback to the controller 114, so as to control operation of the pump 140 and the amount of openness (e.g., throttle valve position) of the valve 142.

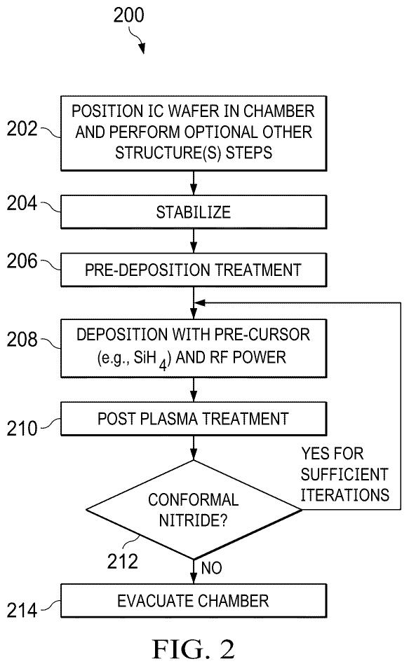

FIG. 2 is a flow diagram of an example method 200 for operating the FIG. 1 system 100. The method 200 forms either an oxide or nitride layer on the semiconductor wafer 104A/104B (either directly on a surface of the wafer front side, or on an exposed material that is affixed to the surface or to another layer(s) relative to the wafer surface front side). The method 200 begins in a step 202, in which the FIG. 1 wafer 104A/104B is obtained and positioned within the process chamber 106. The semiconductor wafer 104A/104B, at this stage, may have incurred some earlier processing steps. Such processing steps may include, for example, wafer cleaning (e.g., chemical and/or mechanical), isolation, possible formation of device well and/or channel and/or source/drain regions, and defining the areas in which an oxide or nitride layer is to be formed.

By way of further example in connection with the step 202, FIG. 3A illustrates a cross-section of the semiconductor wafer 104A/104B in connection with the formation of a split gate flash memory cell 300. At the point in the manufacturing sequence represented in FIG. 3A, the memory cell 300 includes a number of layers, which from bottom upward include: (i) a substrate 302 (e.g., silicon); (ii) a floating gate (FG) insulator layer 304 (e.g., silicon dioxide (SiO₂) or silicon nitride (Si₃N₄), for example having a thickness range from 20 Å to 150 Å (2 nm to 15 nm), formed along and facing the substrate 302 front side; (iii) a FG polysilicon (poly) layer 306, formed along the FG insulator layer 304; (iv) a control gate (CG) insulator layer 308 (e.g., SiO₂), formed for example by in-situ steam generation (ISSG), for example having a thickness range from 10 Å to 20 Å (1 nm to 2 nm) and along the FG poly layer 306; and (v) a CG poly layer 310, formed along the CG insulator layer 308. Accordingly, at the process stage shown in FIG. 3A, the illustrated structure is readied for a next layer to be formed upon the uppermost exposed layer, that is, atop the CG poly layer 310.

Returning to FIG. 2 and its method 200, a sequence of evenly-numbered steps 204 through 214 are next performed. The steps occur, for example, under operation of the controller 114, and form the next desired layer where such a layer is a blanket oxide layer or either a blanket or conformal nitride layer, although such steps also may be used for other layers as well. Generally, of those steps 204 through 214, five steps occur for the formation of the oxide or nitride layer, and step 212 is a conditional step which may repeat certain steps if the nitride is a conformal nitride, as further detailed later. Further, the FIG. 2 method 200 formation of a blanket oxide layer or either a blanket or conformal nitride layer may be used to form layers in addition to those shown in connection with the split gate flash memory cell 300, which is provided by way of example.

Step 204 stabilizes the conditions inside the process chamber 106 before any plasma reaction is caused in that chamber. For example, the step 204 may stabilize all of the gas flows, pressure, temperature, etc., while the radio frequency source 124 is disabled, that is, before the external RF source 124 is activated and the appropriate precursor gases are introduced in contact with the corresponding RF energy. Nonreactive (inert or near inert) gases may be introduced into the process chamber 106 interior, for example using one or more of He or N₂ to assist with the upcoming deposition of either a nitride or oxide layer. Reactive precursor gases also are introduced during the step 204 stabilization, for example including SiH₄ and NH₃ to form nitride, or for example including SiH₄ and N₂O to form oxide. Temperature for the stabilization step 204, and for all subsequent layer-forming steps through step 210, may be in a range from 525° C. to 575° C. to form nitride, and from 280° C. to 560° C. to form oxide. Notably, such temperatures (or selection in the temperature range) may provide various benefit or criticality, and by way of comparison is materially reduced as compared to that required in a furnace process for forming such nitride or oxide. Further, during the stabilization step 204 (and subsequent steps 206 and 208), the FIG. 1 distance du may be set in a range from 350 to 700 mils (thousandths of an inch) (9-18 mm) for nitride formation, or from 400 to 900 mils (10-23 mm) for oxide formation, from the upper surface of the semiconductor wafer 104B. Further, example ranges for the step 204 gas flows (in units of standard cubic centimeters per minute (sccm)), and for the pressure inside the process chamber 106 (in torr, and pascals in parentheses), during the stabilization step 204 are as shown in the following Tables 1 through 3, for each of a blanket nitride layer, a conformal nitride layer, or a blanket oxide layer, respectively.

TABLE 1
Stabilization (blanket nitride layer)

| SiH₄ flow | He flow | NH₃ flow | N₂ flow | Pressure |
|---|---|---|---|---|
| (sccm) | (sccm) | (sccm) | (sccm) | (torr/Pa) |
| 120-200 | 7000-15000 | 600-1000 | 7000-15000 | 2.5-9.5 |
| | | | | (333-1266) |

TABLE 2
Stabilization (conformal nitride layer)

| SiH₄ flow | He flow | NH₃ flow | N₂ flow | Pressure |
|---|---|---|---|---|
| (sccm) | (sccm) | (sccm) | (sccm) | (torr/Pa) |
| 10-50 | 12000-20000 | 50-350 | 5000-12000 | 3-10 |
| | | | | (400-1333) |

TABLE 3
Stabilization (blanket oxide layer)

| SiH₄ flow | He flow | NH₃ flow | N₂ flow | Pressure |
|---|---|---|---|---|
| (sccm) | (sccm) | (sccm) | (sccm) | (torr/Pa) |
| 5-50 | 5000-15000 | 1000-8000 | 0 | 2-9 (267-1200) |

Following the step 204, the step 206 is a pre-deposition treatment that further treats the upper exposed surface on which the upcoming layer will be deposited (e.g., the CG poly layer 310 in FIG. 3A), by enabling the external RF source 124, while discontinuing the flow of the precursor SiH₄ so that no film deposition occurs. The step 206 removes moisture and volatile material from the upper exposed surface onto which the upcoming layer will be deposited. For example, if the uppermost exposed layer is an oxide film from previous processing, nonreactive He and/or N₂ are introduced to reduce/eliminate moisture, remove volatile materials from the oxide, and enrich the surface with bonded nitrogen, so that a subsequent deposited nitride film can have desirable adhesion to the oxide film and a more gradual interface from oxide to nitride. Nonreactive He and/or N₂ may provide similar surface benefits in depositing an oxide, for example along a polysilicon surface. Example ranges for the step 206 gas flows (in sccm), the pressure inside the process chamber 106 (torr, and pascals in parentheses), and RF power (in watts) of the external RF source 124 are as shown in the following Tables 4A through 6A, for each of a blanket nitride layer, a conformal nitride layer, or a blanket oxide layer, respectively. Further, the duration of the pre-deposition treatment step 206 may range from 5 to 25 seconds for a blanket nitride layer, 5 to 20 seconds for a conformal nitride layer, and 5 to 35 seconds for a blanket oxide layer.

TABLE 4A
pre-deposition treatment (blanket nitride layer)

| He flow | N₂ flow | Pressure | |
|---|---|---|---|
| (sccm) | (sccm) | (torr/Pa) | RF power (W) |
| 7000-15000 | 6000-15000 | 5-11 | 175-275 |
| | | (667-1467) | |

TABLE 5A
pre-deposition treatment (conformal nitride layer)

| He flow | N₂ flow | Pressure | RF |
|---|---|---|---|
| (sccm) | (sccm) | (torr/Pa) | power (W) |
| 7000-15000 | 6000-15000 | 5-11 | 175-275 |
| | | (667-1467) | |

TABLE 6A
pre-deposition treatment (blanket oxide layer)

| He flow | N₂O flow | Pressure | RF |
|---|---|---|---|
| (sccm) | (sccm) | (torr/Pa) | power (W) |
| 7000-15000 | 500-10000 | 2-8 (267-1067) | 60-250 |

Various of the above pre-deposition parameters may be tightened in range, for example to achieve certain desirable properties. Additionally, the nonreactive He may have particular benefits and/or criticality for either the nitride or oxide formation. Accordingly, the following Tables 4B through 6B provide additional confinement of ranges:

TABLE 4B
pre-deposition treatment (blanket nitride layer)

| He flow | N₂ flow | Pressure | RF | Temperature |
|---|---|---|---|---|
| (sccm) | (sccm) | (torr/Pa) | power (W) | (° C.) |
| 9000-11000 | 9000-11000 | 7-9 (933-1200) | 210-240 | 545-555 |

TABLE 5B
pre-deposition treatment (conformal nitride layer)

| He flow | N₂ flow | Pressure | RF | Temperature |
|---|---|---|---|---|
| (sccm) | (sccm) | (torr/Pa) | power (W) | (° C.) |
| 9000-11000 | 9000-11000 | 7-9 (933-1200) | 210-240 | 545-555 |

TABLE 6B
pre-deposition treatment (blanket oxide layer)

| He flow | N₂O flow | Pressure | RF | Temperature |
|---|---|---|---|---|
| (sccm) | (sccm) | (torr/Pa) | power (W) | (° C.) |
| 9000-11000 | 3500-4500 | 4-6 (533-800) | 100-140 | 325-375 |

Following the step 206, the step 208 is the deposition step of the desired material (nitride or oxide) on the uppermost exposed surface in the process chamber 106, which is accomplished by continuing to enable the external RF source 124, while also sourcing the appropriate precursor gases to the process chamber 106. In some examples, the RF power of the external RF source 124 is higher in the deposition step 208 than in the pre-deposition treatment step 206. Further as examples, for nitride, SiH₄ is the source of silicon and NH₃ is the source of nitrogen, and for oxide, SiH₄ is the source of silicon and N₂O is the source of oxygen.

For depositing either nitride or oxide, one or more additional nonreactive diluent gases are present, such as N₂ and/or He, and indeed He is present, in relatively large flows, for both the nitride and oxide. Helium does not participate in the chemical reaction, and N₂ if present reacts little if at all, but these gases are thought to create an in-situ sputter effect on the deposited film, thereby removing bound hydrogen from the growing film, which may then be replaced by nitrogen in the case of the nitride film, or oxygen in the case of the oxide film. The resulting film is expected to have properties that more closely resemble thermal oxide or nitride films, e.g. greater breakdown strength and density, and lower leakage. Such films are also expected to source less hydrogen (protons) that may otherwise diffuse and possibly reduce reliability of the IC. Notably, the flow rate of the diluent gas or gases may be significantly greater than in typical baseline oxide and nitride PECVD processes. In some examples the diluent gas flow may be equal to or greater than the flow of one or more of the reactant gases and may be as much as two times or more (even ten times) greater than the SiH₄ reactant gas flow rate, and indeed for the specific ratio of He/SiH₄, that ratio can range from 65 for a blanket nitride to 1,000 or greater for conformal nitride or oxide. Such high flow rates (or flow rate ratios) are thought to result in the aforementioned de-hydrogenation of the resulting films, and to also reduce the rate of film growth, further aiding de-hydrogenation. Example ranges for the step 208 gas flows (sccm), the pressure inside the process chamber 106 (torr, and pascals in parentheses), and RF power (W) of the external RF source 124 are as shown in the following Tables 7A through 9A, for each of a blanket nitride layer, a conformal nitride layer, or a blanket oxide layer, respectively. Notably, a relatively high RF power may be beneficial or provide criticality, for example with respect to any one or more of nitride deposition rate, uniformity, and film quality. In contrast for oxide formation, a relatively lower RF power with slower deposition rate may be achieved. Particularly, the duration of the deposition step 208 may range from 125 to 190 seconds for a blanket nitride layer, 125 to 190 seconds for a conformal nitride layer, and 30 to 70 seconds for a blanket oxide layer, and with a deposition rate of approximately 830 Å/minute for blanket nitride, less than 100 Å/minute for conformal nitride, and less than 75 Å/minute for blanket oxide.

TABLE 7A
deposition (blanket nitride layer)

| SiH₄ | | | | | |
|---|---|---|---|---|---|
| flow | He flow | NH₃ flow | N₂ flow | Pressure | RF power |
| (sccm) | (sccm) | (sccm) | (sccm) | (torr/Pa) | (W) |
| 100-200 | 5000-15000 | 600-1000 | 7000-15000 | 1.5-5 | 120-350 |
| | | | | (200-667) | |

TABLE 8A
deposition (conformal nitride layer)

| SiH₄ | | NH₃ | N₂ | | |
|---|---|---|---|---|---|
| flow | He flow | flow | flow | Pressure | RF power |
| (sccm) | (sccm) | (sccm) | (sccm) | (torr/Pa) | (W) |
| 5-40 | 5000-15000 | 100-500 | 7000-15000 | 5-13 | 150-350 |
| | | | | (667-1733) | |

TABLE 9A
deposition (blanket oxide layer)

| SiH₄ flow | He flow | N₂O flow | N₂ flow | Pressure | RF power |
|---|---|---|---|---|---|
| (sccm) | (sccm) | (sccm) | (sccm) | (torr/Pa) | (W) |
| 5-50 | 5000-15000 | 1000-8000 | 0 | 2-12 | 50-550 |
| | | | | (267-1600) | |

Various of the above deposition parameters may be tightened in range, for example to achieve certain desirable properties In the deposition step, any one or more of RF power, pressure, reactant flow and ratios thereof (e.g., for nitride, one or both of SiH₄ or NH₃; for oxide, one or both of SiH₄ or N₂₀), He flow (including ratio thereof to SiH₄ for either nitride or oxide, and ratio thereof to NH₃ for nitride), may provide benefits or criticality for either nitride or oxide formation, while temperature also may prove such attributes additionally for oxide. Accordingly, the following Tables 7B through 9B provide additional confinement of ranges:

TABLE 7B
deposition (blanket nitride layer)

| SiH₄ | He | NH₃ | N₂ | | RF | |
|---|---|---|---|---|---|---|
| flow | flow | flow | flow | Pressure | power | Temperature |
| (sccm) | (sccm) | (sccm) | (sccm) | (torr/Pa) | (W) | (° C.) |
| 130- | 9000- | 700- | 9000- | 2-3 (267- | 180- | 545- |
| 170 | 11000 | 900 | 11000 | 400) | 220 | 555 |

TABLE 8B
deposition (conformal nitride layer)

| SiH₄ | He | NH₃ | N₂ | | RF | |
|---|---|---|---|---|---|---|
| flow | flow | flow | flow | Pressure | power | Temperature |
| (sccm) | (sccm) | (sccm) | (sccm) | (torr/Pa) | (W) | (° C.) |
| 12- | 9000- | 150- | 9000- | 7-9 (933- | 225- | 545- |
| 18 | 11000 | 250 | 11000 | 1200) | 275 | 555 |

TABLE 9B
deposition (blanket oxide layer)

| SiH₄ | He | N₂O | N₂ | | RF | |
|---|---|---|---|---|---|---|
| flow | flow | flow | flow | Pressure | power | Temperature |
| (sccm) | (sccm) | (sccm) | (sccm) | (torr/Pa) | (W) | (° C.) |
| 8- | 9000- | 3800- | 0 | 7-9 (933- | 80- | 325- |
| 12 | 11000 | 4200 | | 1200) | 120 | 375 |

Following the step 208, the step 210 is a post-deposition treatment of the deposited and exposed material (nitride or oxide) in the process chamber 106, during which the external RF source 124 remains enabled, but all the precursor gases for nitride (SiH₄ and NH₃), and at least one for oxide (SiH₄), are no longer flowed into the chamber. Additionally, one or more nonreactive gases are so provided (e.g., He, N₂) again at flow rates that are relatively high compared to the reactant flow rates in the preceding deposition step 208, and the RF power of the external RF source 124 may be reduced as compared to the deposition step 208, while provided at a level greater than 0 Watts. Further, for the example of an oxide layer, the N₂O from the deposition step 208 also continues to flow. The nitrogen, during this step, serves as a sputter gas rather than a reactant. Accordingly, the step 210 densifies the deposited film and results in a more stoichiometric composition. For example, for nitrides the step 210 may reduce Si—H bonds by removing hydrogen from Si and reacting ionized nitrogen with the resulting dangling Si bonds, thereby increasing film quality and purity. Removing hydrogen also makes the film more electrically robust, as described previously. A similar benefit may be achieved when forming oxide films by removing hydrogen while making oxygen available to the reactive silicon atoms. Example ranges for the gas flows (sccm), the pressure inside the process chamber 106 (torr, and pascals in parentheses), and RF power (W) of the external RF source 124 are as shown in the following Tables 10A through 12A, for each of a blanket nitride layer, a conformal nitride layer, or a blanket oxide layer, respectively. Further, the duration of the post-deposition treatment step 210 may range from 10 to 60 seconds for each of a blanket nitride layer, a conformal nitride layer, and a blanket oxide layer.

TABLE 10A
post-deposition treatment (blanket nitride layer)

| He flow | N₂ flow | Pressure | RF power |
|---|---|---|---|
| (sccm) | (sccm) | (torr/Pa) | (W) |
| 6000-15000 | 10000-18000 | 2.5-8 | 150-550 |
| | | (333-1066) | |

TABLE 11A
post-deposition treatment (conformal nitride layer)

| He flow | N₂ flow | Pressure | RF power |
|---|---|---|---|
| (sccm) | (sccm) | (torr/Pa) | (W) |
| 6000-15000 | 6000-15000 | 2.5-8 | 150-550 |
| | | (333-1066) | |

TABLE 12A
post-deposition treatment (blanket oxide layer)

| He flow | N₂ flow | N₂O flow | Pressure | RF power |
|---|---|---|---|---|
| (sccm) | (sccm) | (sccm) | (torr/Pa) | (W) |
| 6000-15000 | 500-1500 | 1000-8000 | 2.5-8 | 150-550 |
| | | | (333-1066) | |

For the post-deposition step 210, any one or more of temperature, power, pressure, and diluent flow rate may provide benefits and/or criticality. Accordingly, the following Tables 10B through 12B provide additional confinement of ranges:

TABLE 10B
post-deposition treatment (blanket nitride layer)

| He flow | N₂ flow | Pressure | RF power | Temperature |
|---|---|---|---|---|
| (sccm) | (sccm) | (torr/Pa) | (W) | (° C.) |
| 9000-11000 | 13000-15000 | 4-6 | 200-250 | 545-555 |
| | | (533-800) | | |

TABLE 11B
post-deposition treatment (conformal nitride layer)

| He flow | N₂ flow | Pressure | RF power | Temperature |
|---|---|---|---|---|
| (sccm) | (sccm) | (torr/Pa) | (W) | (° C.) |
| 9000-11000 | 9000-11000 | 4-6 | 200-250 | 545-555 |
| | | (533-800) | | |

TABLE 12B
post-deposition treatment (blanket oxide layer)

| | N₂ | N₂O | | RF | |
|---|---|---|---|---|---|
| He flow | flow | flow | Pressure | power | Temperature |
| (sccm) | (sccm) | (sccm) | (torr/Pa) | (W) | (° C.) |
| 9000-11000 | 800-1200 | 3800-4200 | 4-6 | 200-250 | 325-375 |
| | | | (533-800) | | |

As introduced earlier, the step 212 is a conditional step which may repeat certain steps in some uses, such as when the nitride is a conformal spacer nitride. Accordingly, while the method 200 applies to three different types of layers (blanket or conformal nitride; conformal oxide), for the conformal nitride implementation the step 212 will cause the method flow to return to the step 208 and its subsequent step 210, for a number of desirable iterations. The number of iterations may depend, for example, on the overall desired thickness of the final conformal nitride, that is, that nitride may be formed by multiple nitride sub-layers, each being a few nanometers in thickness. It is thought that this protocol provides a benefit by incremental densification of intermediate nitride layers and removal of bound hydrogen. In such instances, the step 206 provides a single pre-deposition treatment for all the nitride sub-layers, while the deposition step 208 and post-deposition treatment step 210 are performed for each of the nitride sub-layers. When the last conformal nitride sub-layer is complete (i.e., the final desired iteration), the method 200 continues to the evacuate chamber step 214.

The step 214 evacuates the interior of the process chamber 106. As part of the evacuation, a desirable amount of N₂ may be flowed through the process chamber 106 interior, to remove any residual gas and particles out of the chamber. Accordingly, step 214 completes the process for the just-deposited layer. Thereafter, one or more additional other layers may be deposited, including for example, another of the three types of layers described herein.

FIG. 3B illustrates the FIG. 3A split gate flash memory cell 300 after the addition of two additional layers, namely, a blanket oxide layer 312 atop the CG poly layer 310, and a blanket nitride layer 314 atop the blanket oxide layer 312. Each of the layers 312 and 314 may be formed with the FIG. 2 method 200, and with the parameter values for the corresponding tables described above for blanket oxide and blanket nitride layers, respectively. The thickness of each of the layers 312 and 314 may be selected based on various considerations, including overall device (and gate) size and function. For example, the blanket oxide layer 312 may be 30-60 Å (3-6 nm) thick, while the blanket nitride layer 314 may be 1,500 Å to 2,000 Å (150-200 nm) thick (not shown to scale in the Figures).

FIG. 3C illustrates the FIG. 3B split gate flash memory cell 300 after additional processing steps. An additional uniform layer of oxide 316 is formed over the layers, for example as protection to a subsequent etch and clean. Then, the structure is then patterned and etched down to the FG poly layer 306 to form first and second gate stacks 318 and 320. Then, two conformal layers are formed over the entire structure: (i) a conformal oxide layer 322 that provides a CG spacer oxide; and (ii) a conformal nitride layer 324 that provides a CG spacer nitride. The conformal oxide layer 322 may be formed, using known processes or using the steps of FIG. 2. The conformal nitride layer 324 may be formed using the FIG. 2 method 200, and may have high compressive stress (−700 MPa) and conformality of 85 percent or greater. Accordingly, the FIG. 2 method 200 thus facilitates the forming of either nitride or oxides, or both, in ICs, including those containing flash memory cells.

Finally, FIG. 3D illustrates the split gate flash memory cell 300 after additional processing steps in which the conformal nitride layer 324 and the conformal oxide layer 322 are partially removed thereby forming control gate sidewall spacers, and the FG polysilicon layer 306 and the FG insulator layer 304 are partially removed thereby forming a floating gate and FG insulator for each of the gate stacks 318, 320. A source line 326 has been formed, e.g. including by ion implantation, and a pre-metal dielectric layer 328 have been formed over the substrate 302. Metal vias 330, e.g. tungsten, connect drain lines 332 to a bitline 334. The gate stacks 318, 320 may be part of an array of similar gate stacks to provide a memory storage device having any desired size.

Nitride and/or oxide layers formed according to the method 200 may provide favorable wet etch rates. In other words, once the layer is formed, subsequent wet etch processes deliver one or more of precision, selectivity, and uniformity. Table 13 below provides examples of the wet etch rates achievable for the three above-described method 200 layers, if etched by dilute hydrofluoric acid (DHF) at a ratio of wafer to HF equal to about 100:1 (0.5-0.6% HF). In some process sequences, or flows, the silicon oxide film may be formed on or over the silicon nitride film, and a portion of the silicon oxide film may be removed in the course of forming certain device features. The relatively low etch rates of the silicon nitride layers, relative to the silicon oxide layer, is expected to provide for selective removal of the silicon oxide film in such examples.

TABLE 13

| Layer type | Wet etch rage (approximate) | |
|---|---|---|
| blanket nitride layer | 15-16 Å/minute | (1.5-1.6 nm/minute) |
| conformal nitride layer | 13 Å/minute | (1.3 nm/minute) |
| blanket oxide layer | 60-65 Å/minute | (6-6.5 nm/minute) |

From the above, one skilled in the art should appreciate that examples are provided for IC semiconductor fabrication, for example with respect to forming IC blanket oxide and both blanket and conformal nitride layers, and by example using a PECVD process. The combination of one or more parameters described in this document along with PECVD process generally may provide one or more of various favorable oxide or nitride layer attributes, as described above. Additionally, while only certain of the oxide or nitride layers in a memory cell 300 have been shown as formed using the PECVD process, the inventive scope may apply to other layers in that cell, or in other semiconductor devices. Further, while blanket oxides have been described, certain of the teachings herein also may apply to conformal oxides. Still further, the use of PECVD further provides benefits as compared to what would be incurred were a baseline furnace process used in an effort to form comparable structures. For example, PECVD allows the use of relatively low temperatures, such as forming nitride at approximately 350° C. and oxide at approximately 550° C., as compared to a higher temperature furnace process (e.g., forming nitride at approximately 740° C. to 780° C. and oxide at approximately 650° C.). As another example, PECVD throughput times may be faster than furnace processes, when performed as described above. As still another example, a furnace process will present its environment, and chemical reactions, to both sides of the semiconductor wafer, so that the formation of certain oxide and/or nitride layers will occur on both sides of the wafer, that is, with a first layer facing the wafer front side (either directly or affixed to one or more other layers on the front side) and with a second layer facing the wafer back side (either directly or affixed to one or more other layers on the back side). As a result, typically the wafer backside subsequently requires various processes, time, cost, and chemistries directed to removing the back side layer(s). In contrast, the improved examples described in this document permit selective layer deposition only relative to the semiconductor wafer front side, thereby eliminating all of the resources that would be required with furnace creation and subsequent removal of wafer back side oxide and nitride layers. As yet another example, furnace processes heretofore used to form nitrides typically create a layer that includes some non-negligible amount of oxygen (e.g., greater than one atomic percent), as may occur due to atmospheric contamination. In contrast, the PECVD method 200, as used to deposit either a blanket or conformal nitride, will result in that layer being substantially oxygen free (e.g., 1 ppm (0.0001%) or less). As a final example, additional modifications are possible in the described embodiments, and other embodiments are possible, within the scope of the following claims.

What is claimed is:

1. A method of forming at least one of a nitride or oxide layer for an integrated circuit, the method comprising:
positioning a semiconductor wafer in a processing chamber, the semiconductor wafer including a wafer front side and the processing chamber including differential surfaces adapted to be coupled to a plasma-igniting external radio frequency source;
depositing one of a nitride or oxide over the wafer front side by reacting at least two precursor gases for a selected one of the nitride or oxide layer in the chamber while the plasma igniting external radio frequency source is enabled; and
post-treating the one of a nitride or oxide with the plasma igniting external radio frequency source enabled and with exposure to helium and nitrogen in the absence of at least one of the at least two precursor gases.

2. The method of claim 1, wherein the selected one of the nitride or oxide layer is a blanket nitride and the at least two precursor gases include SiH₄ flowed into the processing chamber during the depositing at a rate from 100 sccm to 200 sccm and NH₃ flowed into the processing chamber at a rate from 600 sccm to 1000 sccm.

3. The method of claim 2 and further including, during the depositing, flowing helium into the chamber at a rate from 7000 sccm to 15000 sccm.

4. The method of claim 1, wherein the selected one of the nitride or oxide layer is a conformal nitride and the at least two precursor gases include SiH₄ flowed into the processing chamber during the depositing at a rate from 5 sccm to 40 sccm and NH₃ flowed into the processing chamber at a rate from 100 sccm to 500 sccm.

5. The method of claim 4 and further including, during the depositing, flowing helium into the chamber at a rate from 7000 sccm to 18000 sccm.

6. The method of claim 1, wherein the selected one of the nitride or oxide layer is a nitride and, during the deposition, the plasma igniting external radio frequency source is enabled at a power from 120 W to 350 W.

7. The method of claim 1, wherein the selected one of the nitride or oxide layer is an oxide and the at least two precursor gases include SiH₄ flowed into the processing chamber during the depositing at a rate from 5 sccm to 50 sccm and N₂O flowed into the processing chamber at a rate from 1000 sccm to 8000 sccm.

8. The method of claim 1, wherein the selected one of the nitride or oxide layer is an oxide and, during the deposition, the plasma igniting external radio frequency source is enabled at a power from 50 W to 550 W.

9. The method of claim 1, wherein the selected one of the nitride or oxide layer is a blanket nitride and, during the deposition, pressure in the chamber is from 1.5 torr to 5 torr.

10. The method of claim 1, wherein the selected one of the nitride or oxide layer is a conformal nitride and, during the deposition, pressure in the chamber is from 5 torr to 13 torr.

11. The method of claim 1, wherein the selected one of the nitride or oxide layer is an oxide and, during the deposition, pressure in the chamber is from 2 torr to 12 torr.

12. The method of claim 1, wherein the selected one of the nitride or oxide layer is a nitride and, during the post-treating, temperature in the chamber is in a range from 525° C. to 575° C.

13. The method of claim 1, wherein the selected one of the nitride or oxide layer is an oxide and, during the post-treating, temperature in the chamber is in a range from 280° C. to 560° C.

14. The method of claim 1, wherein during the post-treating, the plasma igniting external radio frequency source is enabled at a power from 150 W to 550 W.

15. The method of claim 1, wherein during the post-treating, flowing helium into the chamber at a rate from 6000 sccm to 15000 sccm.

16. The method of claim 1, wherein the selected one of the nitride or oxide layer is a blanket nitride and, during the post-treating, flowing N₂ into the chamber at a rate from 10000 sccm to 18000 sccm.

17. The method of claim 1, wherein the selected one of the nitride or oxide layer is a conformal nitride and, during the post-treating, flowing N₂ into the chamber at a rate from 6000 sccm to 15000 sccm.

18. The method of claim 1, wherein the selected one of the nitride or oxide layer is an oxide and, during the post-treating, flowing N₂O into the chamber at a rate from 1000 sccm to 8000 sccm and N₂ into the chamber at a rate from 500 sccm to 1500 sccm.

19. The method of claim 1, wherein during the post-treating, pressure in the chamber is from 2.5 torr to 8 torr.

20. An integrated circuit, comprising:
a semiconductor wafer; and
a silicon nitride layer over the semiconductor wafer that is substantially oxygen free.

21. The integrated circuit of claim 20, wherein the silicon nitride layer has a wet etch rate of 16 Å/minute or less in 100:1 diluted hydrofluoric acid.

22. The integrated circuit of claim 20, wherein the nitride layer includes 1 ppm or less of oxygen.
